(19) United States
(12) Patent Application Publication
(10) Pub. No.: US 2023/0238371 A1
(43) Pub. Date: Jul. 27, 2023

(54) DISPLAY DEVICE

(71) Applicant: Samsung Display Co., LTD., Yongin-si (KR)

(72) Inventor: Sang Hoon LEE, Hwaseong-si (KR)

(73) Assignee: Samsung Display Co., LTD., Yongin-si, Gyeonggi-do (KR)

(21) Appl. No.: 17/968,080

(22) Filed: Oct. 18, 2022

(30) Foreign Application Priority Data
Jan. 26, 2022 (KR) 10-2022-0011235

(51) Int. Cl. H01L 25/16; G09G 3/3233

(52) U.S. Cl. CPC H01L 25/167; G09G 3/3233; G09G 2300/0842; G09G 2300/0426

(57) ABSTRACT

A display device includes a plurality of sub-pixels including emission areas, and a subsidiary area, a via layer disposed on a substrate, a bank layer disposed on the via layer and separating emission areas of the plurality of sub-pixels from one another, a dam portion disposed between the bank layer and adjacent bank layer and separating a bank storage portion from the subsidiary area, a first electrode and a second electrode disposed on the via layer in one of the emission areas and spaced apart from each other, and a light-emitting element disposed on the first electrode and the second electrode. The bank layer includes a bank guide portion disposed between the one of the emission areas and the bank storage portion, and a shape of the bank guide portion is different from a shape of a rest of the bank layer in a cross-sectional view.

### CROSS REFERENCE TO RELATED APPLICATION(S)

This application claims priority to and benefit of Korean Patent Application No. 10-2022-0011235 under 35 U.S.C. § 119, filed on Jan. 26, 2022, in the Korean Intellectual Property Office (KIPO), the disclosure of which is incorporated by reference herein in its entirety.

### BACKGROUND

### 1. Technical Field

The disclosure relates to a display device.

### 2. Description of the Related Art

Display devices become more and more important as multimedia technology evolves. Accordingly, a variety of types of display devices such as organic light-emitting display (OLED) devices and liquid-crystal display (LCD) devices are currently used.

Display devices include a display panel such as an organic light-emitting display panel and a liquid-crystal display panel for displaying images. Among them, light-emitting display panel may include light-emitting elements. For example, light-emitting diodes (LEDs) may include an organic light-emitting diode (OLED) using an organic material as a luminescent material, and an inorganic light-emitting diode using an inorganic material as a luminescent material.

### SUMMARY

Aspects of the disclosure provide a display device that can prevent ink containing light-emitting elements from overflowing.

It should be noted that objects of the disclosure are not limited to the above-mentioned object; and other objects of the disclosure will be apparent to those skilled in the art from the following descriptions.

According to an embodiment of the disclosure, a display device may include a plurality of sub-pixels including emission areas, and a subsidiary area, a via layer disposed on a substrate, a bank layer disposed on the via layer and separating the emission areas of the plurality of sub-pixels from one another, a dam portion disposed between the bank layer and adjacent bank layer and separating the bank storage portion from the subsidiary area, a first electrode and a second electrode disposed on the via layer in at least one of the emission areas and spaced apart from each other, and a light-emitting element disposed on the first electrode and the second electrode. The bank layer may include a bank guide portion disposed between the at least one of the emission areas and the bank storage portion, and a shape of the bank guide portion may be different from a shape of a rest of the bank layer in a cross-sectional view.

In an embodiment, the emission areas may be spaced apart from one another in a first direction, the bank storage portion may be spaced apart from the emission areas in a second direction intersecting the first direction, the subsidiary area may be spaced apart from the bank storage portion in the second direction, and the bank storage portion may be disposed between the emission areas and the subsidiary area.

In an embodiment, the shape of the bank guide portion in the cross-sectional view mat be defined by cutting the bank guide portion in the second direction, and the shape of the rest of the bank layer in the cross-sectional view may be defined by cutting the bank layer in the second direction.

In an embodiment, a width of the bank guide portion may be smaller than a width of the rest of the bank layer in the second direction.

In an embodiment, a height of the bank guide portion may be equal to a height of the rest of the bank layer in a thickness direction of the bank layer.

In an embodiment, a height of the bank guide portion may be smaller than a height of the rest of the bank layer in a thickness direction of the bank layer.

In an embodiment, a width of the bank guide portion may be equal to a width of the rest of the bank layer in the second direction.

In an embodiment, the dam portion may extend in the first direction, and a height of the dam portion may be equal to a height of the bank layer in a thickness direction of the bank layer.

In an embodiment, a width of the dam portion may be smaller than a width of the bank layer in the second direction.

In an embodiment, the dam portion may include a plurality of dam extensions extending in the second direction and disposed adjacent to the bank guide portion, and the plurality of dam extensions and the bank layer may be integral with each other.

In an embodiment, the bank storage portion may be defined by the plurality of dam extension, the bank layer including the bank guide portion, and the dam portion.

In an embodiment, the bank storage portion may be in one to one correspondence with each of the emission areas of the plurality of sub-pixels in the second direction.

In an embodiment, the bank guide portion may be disposed between the at least one of the emission areas and the bank storage portion, and may be in contact with the at least one of the emission areas and the bank storage portion.

In an embodiment, the dam portion and the bank layer may be disposed on a same layer and may include a same material.

According to an embodiment of the disclosure, a display device may include a plurality of sub-pixels including emission areas, and a subsidiary area, a via layer disposed on a substrate, a bank layer disposed on the via layer and separating emission areas of the plurality of sub-pixels from one another, a dam portion surrounded by the bank layer on the via layer and separating a bank storage portion from a subsidiary area, a first electrode and a second electrode disposed on the via layer in at least one of the emission areas and spaced apart from each other, and a light-emitting element disposed on the first electrode and the second electrode. The bank storage portion and the subsidiary area may be surrounded by the bank layer and may be separated and divided by the dam portion, the bank layer may include a bank guide portion disposed between the at least one of the emission areas and the bank storage portion, and a shape of the bank guide portion may be different from a shape of a rest of the bank layer in a cross-sectional view.

In an embodiment, the emission areas may be spaced apart from one another in a first direction, the bank storage portion may be spaced apart from the emission areas in a second direction intersecting the first direction, the subsidiary area may be spaced apart from the bank storage portion in the second direction, and the bank storage portion may be disposed between the emission areas and the subsidiary area.

In an embodiment, the first electrode may extend to the subsidiary area, and the subsidiary area may include a separation region disconnecting the first electrode.

In an embodiment, the dam portion may be disposed between the bank guide portion and the separation region, and may not overlap the separating region in a plan view.

In an embodiment, the bank layer and the dam portion may be integral with each other, may be disposed on a same layer and may include a same material.

In an embodiment, the display device may further include a first connection electrode in electrical contact with a first end of the light-emitting element, and a second connection electrode in electrical contact with a second end of the light-emitting element. The first connection electrode and the second connection electrode may overlap the at least one of the emission areas in a plan view, and may not overlap the bank storage portion in the plan view.

According to the embodiments of the disclosure, a bank guide portion and a dam portion may be formed in a display device, so that an ink that flows over an emission area may be guided to flow into a bank storage portion. Accordingly, it is possible to prevent bright spots, dark spots, film delamination, etc., which may occur if the ink overflows into a separation region of the subsidiary area.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a plan view of a display device according to an embodiment of the disclosure.

FIG. 2 is a schematic diagram of an equivalent circuit of a sub-pixel of a display device according to an embodiment of the disclosure.

FIG. 3 is a plan view showing a pixel of a display device according to an embodiment of the disclosure.

FIG. 4 is a plan view showing the second sub-pixel of FIG. 3.

FIG. 5 is a schematic cross-sectional view taken along line Q1-Q1′ of FIG. 4.

FIG. 6 is a schematic cross-sectional view taken along line Q2-Q2′ of FIG. 4.

FIG. 7 is a schematic cross-sectional view showing an embodiment of a bank guide portion, taken along line Q3-Q3′ of FIG. 4.

FIGS. 8 to 10 are schematic cross-sectional views showing another embodiment of the bank guide portion.

FIG. 11 is a schematic cross-sectional view taken along line Q4-Q4′ of FIG. 4.

FIG. 12 is a perspective view showing a light-emitting element according to an embodiment of the disclosure.

FIG. 13 is a plan view showing a pixel of a display device according to another embodiment of the disclosure.

FIG. 14 is a plan view showing the first sub-pixel of FIG. 13.

FIG. 15 is a schematic cross-sectional view taken along line Q5-Q5′ of FIG. 14.

FIG. 16 is a plan view showing a pixel of a display device according to yet another embodiment of the disclosure.

FIG. 17 is a schematic cross-sectional view taken along line Q6-Q6′ of FIG. 16.

### DETAILED DESCRIPTION OF THE EMBODIMENTS

The disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

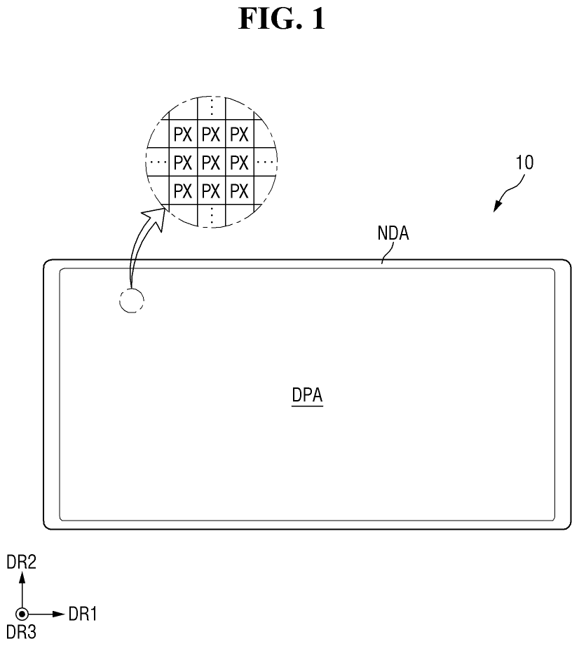

FIG. 1 is a plan view of a display device according to an embodiment of the disclosure.

Referring to FIG. 1, the display device 10 may display a moving image or a still image. A display device 10 may refer to any electronic device that provides a display screen. For example, the display device 10 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device 10 may include a display panel for providing a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel 10, but the disclosure is not limited thereto. Any other display panel may be employed as long as the technical idea of the disclosure can be equally applied.

A first direction DR1, a second direction DR2, and a third direction DR3 are defined in the drawings. The display device 10 according to the embodiments of the disclosure will be described with reference to the drawings. The first direction DR1 may be perpendicular to the second direction DR2 in a plane. The third direction DR3 may be perpendicular to the plane where the first direction DR1 and the second direction DR2 are located. The third direction DR3 may be perpendicular to each of the first direction DR1 and the second direction DR2. In the following description of the display devices 10 according to the embodiments of the disclosure, the third direction DR3 may refer to the thickness direction of the display device 10.

The shape of the display device 10 may be modified in a variety of ways. For example, the display device 10 may have a rectangular shape including longer sides in the first direction DR1 and shorter sides in the second direction DR2 in a plan view. In another example, the display device 10 may have a rectangular shape including longer sides in the second direction DR2 and shorter sides in the first direction DR1 in a plan view. It should be understood that the disclosure is not limited thereto. The display device 10 may have a variety of shapes such as a square, a quadrangle with rounded corners (vertices), other polygons, and a circle. The shape of a display area DPA of the display device 10 may also be similar to the overall shape of the display device 10. FIG. 1 shows the display device 10 and the display area DPA in the shape of a rectangle having longer side in the first direction DR1 and shorter sides in the second direction DR2.

The display device 10 may include a display area DPA and a non-display area NDA. In the display area DPA, images may be displayed. In the non-display area NDA, images may be not displayed. The display area DPA may be referred to as an active area, while the non-display area NDA may be referred to as an inactive area. The display area DPA may generally occupy the center of the display device 10.

The display area DPA may include multiple pixels PX. The multiple pixels PX may be arranged in a matrix. The shape of each pixel PX may be, but is not limited to, a rectangle or a square in a plan view. Each pixel may have a diamond shape having sides inclined with respect to a direction. The pixels PX may be arranged in stripes or the PenTile™ alternately. Each of the pixels PX may include at least one light-emitting element that emits light of a particular wavelength band to represent a color.

The non-display area NDA may be disposed adjacent to the display area DPA. The non-display area NDA may surround the display area DPA entirely or partially. The display area DPA may have a rectangular shape, and the non-display area NDA may be disposed to be adjacent to the four sides of the display area DPA. The non-display area NDA may form the bezel of the display device 10. Lines or circuit drivers included in the display device 10 may be disposed in each of the non-display area NDA, or external devices may be mounted.

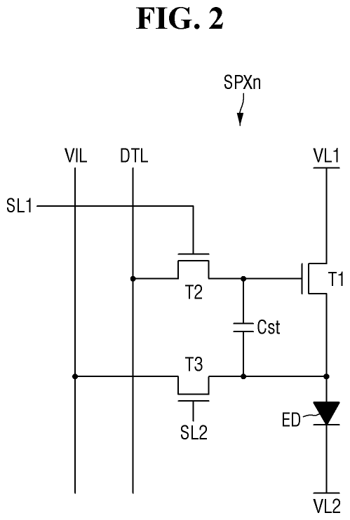

FIG. 2 is a schematic diagram of an equivalent circuit of a sub-pixel of a display device according to an embodiment of the disclosure.

Referring to FIG. 2, each of the sub-pixels SPXn of the display device 10 according to an embodiment may include three transistors T1, T2 and T3 and one storage capacitor Cst in addition to a light-emitting element ED.

The light-emitting element ED may emit light in proportional to the current supplied through the first transistor T1. The light-emitting element ED may emit light in a particular wavelength range by an electric signal transmitted from a first electrode and a second electrode electrically connected to the both ends, respectively.

A first end of the light-emitting element ED may be electrically connected to the source electrode of the first transistor T1, and a second end thereof may be electrically connected to a second voltage line VL2 to receive a low-level voltage (hereinafter referred to as a second supply voltage) lower than a high-level voltage (hereinafter referred to as a first supply voltage) from a first voltage line VL1.

The first transistor T1 may adjust a current flowing from the first voltage line VL1 from which the first supply voltage is supplied to the light-emitting element ED based on the voltage difference between a gate electrode and the source electrode. For example, the first transistor T1 may be a driving transistor for driving the light-emitting element ED. The gate electrode of the first transistor T1 may be electrically connected to the source electrode of the second transistor T2, and the source electrode of the first transistor T1 may be electrically connected to the first end of the light-emitting element ED. The drain electrode of the first transistor T1 may be electrically connected to a first voltage line VL1 to receive the first supply voltage.

The second transistor T2 may be turned on by a scan signal of the first scan line SL1 to electrically connect the data line DTL with the gate electrode of the first transistor T1. The gate electrode of the second transistor T2 may be electrically connected to the first scan line SL1, the source electrode thereof may be electrically connected to the gate electrode of the first transistor T1, and the drain electrode thereof may be electrically connected to the data line DTL.

A third transistor T3 may be turned on by a scan signal of a second scan line SL2 to electrically connect the initialization voltage line VIL with the first end of the light-emitting element ED. The gate electrode of the third transistor T3 may be electrically connected to the second scan line SL2, the drain electrode thereof may be electrically connected to the initialization voltage line VIL, and the source electrode thereof may be electrically connected to one end of the light-emitting element ED or the source electrode of the first transistor T1. Although the first scan line SL1 and the second scan line SL2 are separately depicted in the drawings, the disclosure is not limited thereto. In some embodiments, the first scan line SL1 and the second scan line SL2 may be made up of a single line, and the second transistor T2 and the third transistor T3 may be turned on simultaneously by the same scan signal.

The source electrode and the drain electrode of each of the transistors T1, T2 and T3 are not limited to those described above. They may be electrically connected in the opposite way. Each of the transistors T1, T2 and T3 may be formed as a thin-film transistor. Although each of the transistors T1, T2 and T3 implemented as an n-type MOSFET (metal oxide semiconductor field effect transistor) in the embodiment shown in FIG. 2, the disclosure is not limited thereto. For example, each of the transistors T1, T2 and T3 may be implemented as a p-type MOSFET, or some of the transistors T1, T2 and T3 may be implemented as n-type MOSFETs while the others may be implemented as p-type MOSFETs.

The storage capacitor Cst may be formed between the gate electrode and the source electrode of the first transistor T1. The storage capacitor Cst may store a voltage difference between the gate voltage and the source voltage of the first transistor T1.

Hereinafter, the structure of a pixel PX of the display device 10 according to an embodiment will be described in detail with reference to other drawings.

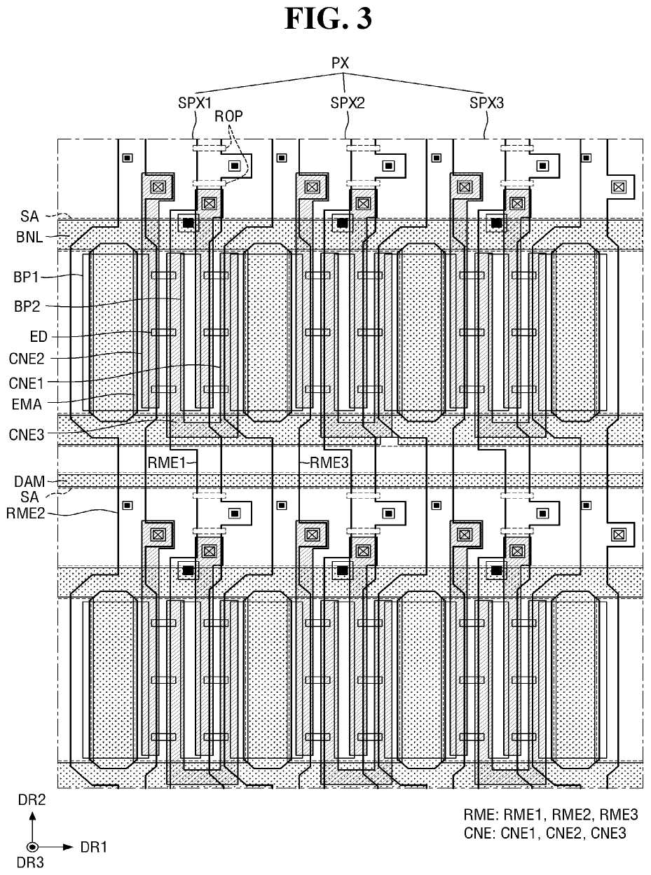

FIG. 3 is a plan view showing a pixel of a display device according to an embodiment of the disclosure.

Referring to FIG. 3, each of the pixels SPX of the display device 10 may include multiple sub-pixels PXn, where n is an integer from one to three. For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be red, the second color may be green, and the third color may be blue. It is, however, to be understood that the disclosure is not limited thereto. All the sub-pixels SPXn may emit light of the same color. According to another embodiment of the disclosure, each of the sub-pixels SPXn may emit blue light. Although the pixel PX includes three sub-pixels SPXn in FIG. 3, the disclosure is not limited thereto. The pixel PX may include more than three sub-pixels SPXn.

Each of the sub-pixels SPXn of the display device 10 may include an emission area EMA and a non-emission area. In the emission area EMA, light-emitting elements ED may be disposed to emit light of a particular wavelength. In the non-emission area, no light-emitting element ED is disposed, and light emitted from the light-emitting elements ED do not reach and thud no light exits therefrom. The emission area EMA may include an area in which the light-emitting elements ED are disposed, and may include an area adjacent to the light-emitting elements ED where lights emitted from the light-emitting elements ED exit.

It is, however, to be understood that the disclosure is not limited thereto. The emission area EMA may also include an area in which light emitted from the light-emitting elements ED is reflected or refracted by other elements to exit. Multiple light-emitting elements ED may be disposed in each of the sub-pixels SPXn, and the emission area EMA may include the area where the light-emitting elements are disposed and adjacent areas.

Although the emission areas EMA of the sub-pixels SPXn have the substantially uniform area in the drawings, the disclosure is not limited thereto. In some embodiments, the emission areas EMA of the sub-pixels SPXn may have different areas depending on a color or wavelength band of light emitted from the light-emitting elements ED disposed in the respective sub-pixels SPXn.

Each of the sub-pixels SPXn may also include a subsidiary area SA disposed in the non-emission area. The subsidiary area SA may be disposed adjacent to the emission area EMA in the second direction DR2, and may be disposed between the adjacent emission areas EMA of the sub-pixels PXn in the second direction DR2. For example, multiple emission areas EMA may be spaced apart from one another in the first direction DR1, and the emission areas EMA and the subsidiary area SA may be repeatedly and alternately arranged in the second direction DR2. It is, however, to be understood that the disclosure is not limited thereto. The emission areas EMA and the subsidiary area SA of the pixels PX may have an arrangement different from that of FIG. 3. In the pixel PX shown in FIG. 3, an emission area EMA and a subsidiary area SA on the upper side of the emission area EMA in the second direction DR2 may be included in a sub-pixel SPXn, and the subsidiary area SA on the opposite side of the emission area EMA in the second direction DR2 may be the subsidiary area SA of another sub-pixel SPXn. According to this embodiment, the subsidiary area SA may be continuously extended across the sub-pixels SPXn and may be continuously extended across pixels PXn.

A bank layer BNL may be disposed between the subsidiary area SA and the emission areas EMA, and the distance between them may vary depending on the width of the bank layer BNL. No light-emitting element ED may be disposed in the subsidiary area SA and thus no light may exit therefrom. Electrodes RME1, RME2 and RME3 disposed in the sub-pixels PXn may be partially disposed in the subsidiary area SA. Some of the electrodes RME disposed in different sub-pixels SPXn may be disconnected at separation regions ROP of the subsidiary area SA.

The bank layer BNL may be arranged in a ladder pattern on the front surface of the display area DPA including portions extended in the first direction DR1 and the second direction DR2 in a plan view. The bank layer BNL may be disposed along the border of each of the sub-pixels SPXn to distinguish adjacent sub-pixels PXn. The bank layer BNL may be disposed to surround the emission area EMA disposed in each of the sub-pixels SPXn to distinguish them. The bank layer BNL may separate the emission area EMA from the subsidiary area SA.

The display device 10 may include multiple electrodes RME: RME1, RME2 and RME3, multiple bank patterns BP1 and BP2, multiple light-emitting elements ED: ED1 and ED2, and multiple connection electrodes CNE: CNE1, CNE2 and CNE3. The elements will be described later.

Each pixel PX or sub-pixel SPXn of the display device 10 may include a pixel driver circuit. The above-described lines may pass through each of the pixels PX or the periphery thereof to receive a driving signal from the pixel driver circuit. The pixel driver circuit may include a transistor and a capacitor. The numbers of transistors and capacitors of each pixel driver circuit may be changed in a variety of ways. According to an embodiment of the disclosure, a pixel driver circuit of each of the sub-pixels SPXn of the display device 10 may have a 3T1C structure, i.e., it may include three transistors and one capacitor, as shown in FIG. 2. It should be understood that the disclosure is not limited thereto. The pixel driver circuit may employ a variety of other modified pixel structures PX such as a 2T1C structure, a 7T1C structure, and a 6T1C structure.

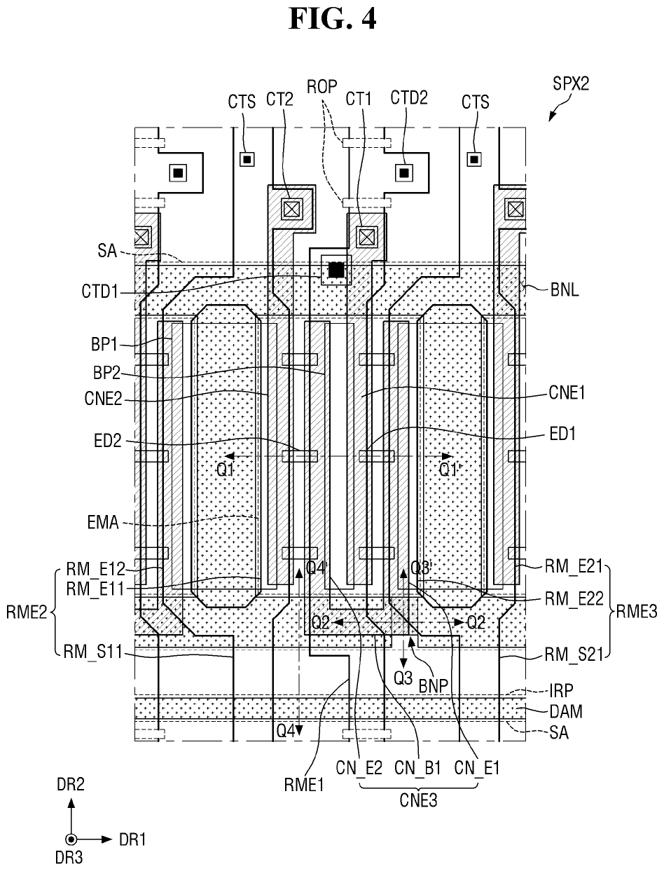

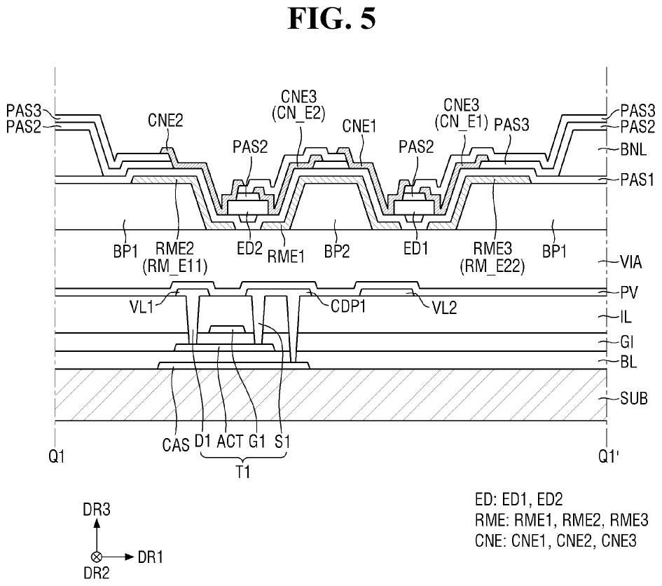

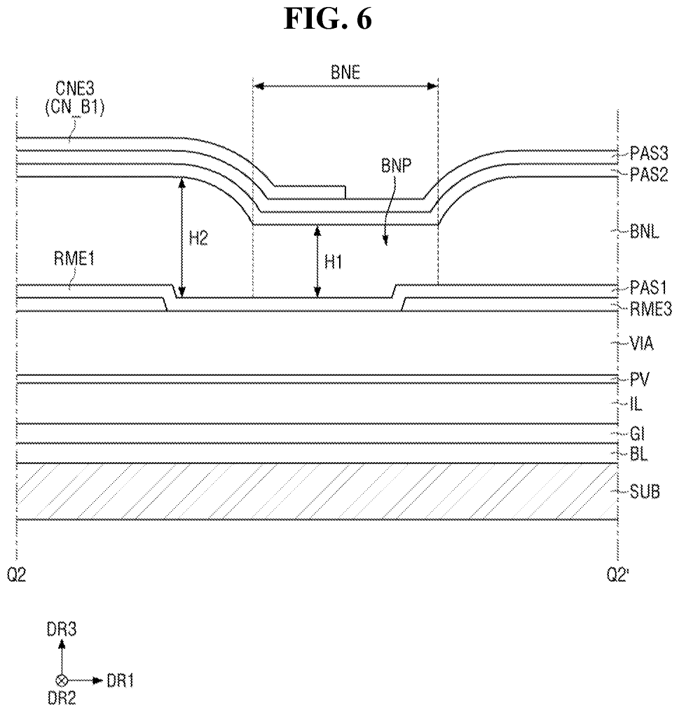

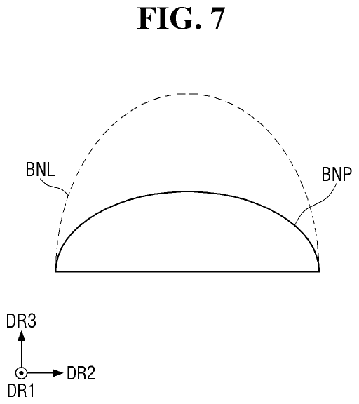

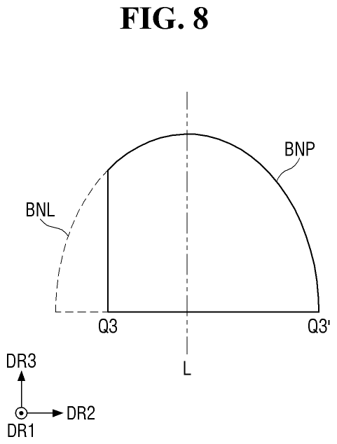

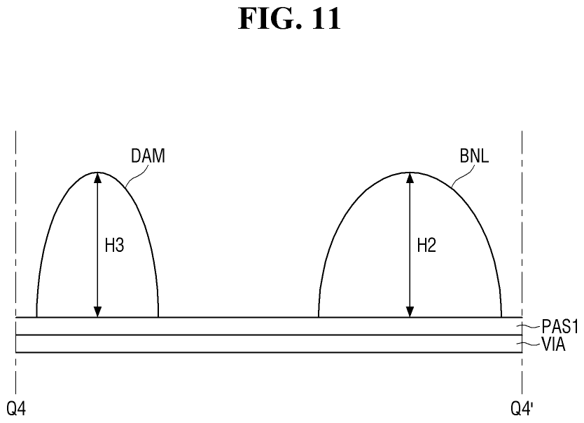

FIG. 4 is a plan view showing the second sub-pixel of FIG. 3. FIG. 5 is a schematic cross-sectional view taken along line Q1-Q1′ of FIG. 4. FIG. 6 is a schematic cross-sectional view taken along line Q2-Q2′ of FIG. 4. FIG. 7 is a schematic cross-sectional view showing an embodiment of a bank guide portion, taken along line Q3-Q3′ of FIG. 4. FIGS. 8 to 10 are schematic cross-sectional views showing another embodiment of the bank guide portion. FIG. 11 is a schematic cross-sectional view taken along line Q4-Q4′ of FIG. 4.

Referring to FIGS. 4 to 11 in conjunction with FIG. 3, the display device 10 may include a substrate SUB, a semiconductor layer disposed on the substrate SUB, multiple conductive layers, and multiple insulating layers. The semiconductor layer, the conductive layers, and the insulating layers may form a circuit layer and a display element layer of the display device 10.

For example, the substrate SUB may be an insulating substrate. The substrate SUB may be made of an insulating material such as glass, quartz and a polymer resin. The substrate SUB may be either a rigid substrate or a flexible substrate that can be bent, folded, or rolled.

A first conductive layer may be disposed on the substrate SUB. The first conductive layer may include a bottom metal layer CAS. The bottom metal layer CAS may be disposed to overlap an active layer ACT of the first transistor T1. The bottom metal layer CAS may include a material that blocks light, and thus may prevent light from entering the active layer ACT of the first transistor T1. It is, however, to be noted that the bottom metal layer CAS may be omitted.

A buffer layer BL may be disposed on the bottom metal layer CAS and the substrate SUB. The buffer layer BL may be formed on the substrate SUB to protect the transistors from moisture permeating through the substrate SUB that is susceptible to moisture permeation, and may also provide a flat surface.

The semiconductor layer may be disposed on the buffer layer BL. The semiconductor layer may include the active layer ACT of the first transistor T1. The active layer ACT may be disposed to partially overlap a gate electrode G1 of a second conductive layer, which will be described later.

The semiconductor layer may include polycrystalline silicon, monocrystalline silicon, an oxide semiconductor, etc. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium-gallium zinc tin oxide (IGZTO), etc.

Although only one first transistor T1 is disposed in the sub-pixel SPXn of the display device 10 in the drawing, the disclosure is not limited thereto. Multiple transistors may be included in the display device 10.

A gate insulator GI may be disposed on the active layer ACT. The gate insulator GI may work as a gate insulating film of the first transistor T1.

The second conductive layer may be disposed on the gate insulator GI. The second conductive layer may include a gate electrode G1 of the first transistor T1. The gate electrode G1 may be disposed so that it overlaps a channel region of the active layer ACT in the thickness direction, i.e., a third direction DR3.

An interlayer dielectric layer IL may be disposed on the second conductive layer. The interlayer dielectric layer IL may work as an insulating film between the second conductive layer and other layers disposed thereon and may protect the second conductive layer.

A third conductive layer may be disposed on the interlayer dielectric layer IL. The third conductive layer may include a first voltage line VL1, a second voltage line VL2, and a conductive pattern CDP1.

A high-level voltage (or a first supply voltage) may be applied to the first voltage line VL1 to be transmitted to the first electrode RME1, and a low-level voltage (or a second supply voltage) may be applied to the second voltage line VL2 to be transmitted to the second electrode RME2. A portion of the first voltage line VL1 may be in contact with the active layer ACT of the first transistor T1 through a contact hole penetrating the interlayer dielectric layer IL and the gate insulator GI. The first voltage line VL1 may work as the first drain electrode D1 of the first transistor T1. The second voltage line VL2 may be directly connected to the second electrode RME2 to be described later. The first voltage line VL1 may be electrically connected to a first connection electrode CNE1 to be described later, and the second voltage line VL2 may be electrically connected to a second connection electrode CNE2 to be described later.

The first conductive pattern CDP1 may be in contact with the active layer ACT of the first transistor T1 through a contact hole penetrating the interlayer dielectric layer IL and the gate insulator GI. The first conductive pattern CDP1 may be in contact with the bottom metal layer CAS through another contact hole. The first conductive pattern CDP1 may work as a source electrode S1 of the first transistor T1.

A passivation layer PV may be disposed on the third conductive layer and the interlayer dielectric layer IL. The passivation layer PV may work as an insulating film between the third conductive layer and other layers disposed thereon and may protect the third conductive layer.

The buffer layer BL, the gate insulator GI, the interlayer dielectric layer IL, and the passivation layer PV may be made up of multiple inorganic layers alternately stacked each other. For example, the buffer layer BL, the gate insulator GI, the interlayer dielectric layer IL, and the passivation layer PV may be made up of a double layer in which inorganic layers including at least one of silicon oxide (SiOx), silicon nitride (SiNx), and silicon oxynitride (SiON) are stacked each other or multiple layers in which they are alternately stacked each other. It is, however, to be understood that the disclosure is not limited thereto. The buffer layer BL, the gate insulator GI, the interlayer dielectric layer IL, and the passivation layer PV may be made up of a single inorganic layer including the above-described insulating material. In some embodiments, the interlayer dielectric film IL may be made of an organic insulating material such as polyimide (PI).

The second conductive layer and the third conductive layer may be made up of a single layer or multiple layers including one of molybdenum (Mo), aluminum (Al), chromium (Cr), gold (Au), titanium (Ti), nickel (Ni), neodymium (Nd), and copper (Cu) or an alloy thereof. It is, however, to be understood that the disclosure is not limited thereto.

A via layer VIA may be disposed on the passivation layer PV. The via layer VIA may include an organic insulating material, e.g., an organic insulating layer material such as polyimide (PI), to provide a flat surface.

The electrodes RME: RME1, RME2 and RME3, the bank patterns BP1 and BP2, the light-emitting elements ED: ED1 and ED2, and the connection electrodes CNE: CNE1, CNE2, CNE and CNE4 may be disposed on the via layer VIA as a display element layer. Multiple insulating layers PAS1, PAS2 and PAS3 may be also disposed on the via layer VIA.

The bank patterns BP1 and BP2 may be disposed directly on the via layer VIA. The bank patterns BP1 and BP2 may include first bank patterns BP1 and a second bank pattern BP2. The first bank patterns BP1 may be disposed across the emission area EMA and the non-emission area of the sub-pixel SPXn. The first bank patterns BP1 may be disposed across the adjacent sub-pixels SPXn in the first direction DR1. The first bank patterns BP1 may have a shape extended in the second direction DR2 and may be spaced apart from one another in the first direction DR1. The first bank patterns BP1 may have the same width, but the disclosure is not limited thereto. They may have different widths. The length of the first bank patterns BP1 extended in the second direction DR2 may be smaller than the length of the emission area EMA surrounded by the bank layer BNL in the second direction DR2.

The second bank pattern BP2 may be disposed in the emission area EMA of the sub-pixel SPXn and may have a shape extended in the second direction DR2. The second bank pattern BP2 may be disposed between the first bank patterns BP1 such that it is spaced apart from the first bank patterns BP1. The second bank pattern BP2 may form an island-shaped pattern extended in the second direction DR2 having a smaller width in the emission area EMA of each sub-pixel SPXn on the front surface of the display area DPA.

The second bank pattern BP2 may be disposed at the center of the emission area EMA, and the first bank patterns BP1 may be disposed to be spaced apart from each other with the second bank pattern BP2 therebetween. The first bank patterns BP1 and the second bank pattern BP2 may be arranged alternately in the first direction DR1. Light-emitting elements ED may be disposed between the first bank patterns BP1 and the second bank pattern BP2 spaced apart from each other.

The first bank patterns BP1 and the second bank pattern BP2 may have the same length in the second direction DR2, but may have different widths measured in the first direction DR1. A portion of the bank layer BNL that is extended in the second direction DR2 may overlap the first bank patterns BP1 in the thickness direction (e.g., in the third direction DR3). The bank patterns BP1 and BP2 may be arranged in island-shaped patterns on the front surface of the display area DPA. The light-emitting elements ED may be disposed between the bank patterns BP1 and BP2 spaced apart from each other.

The bank patterns BP1 and BP2 may have a structure that at least partly protrudes from the upper surface of the via layer VIA. The protruding portions of the bank patterns BP1 and BP2 may have inclined or curved side surfaces. Unlike that shown in the drawings, the bank patterns BP1 and BP2 may have a shape of a semi-circular outer surface or s semi-elliptical outer surface in the cross-sectional view. The bank patterns BP1 and BP2 may include, but is not limited to, an organic insulating material such as polyimide (PI).

The electrodes RME may have a shape extended in a direction and may be disposed in each of the sub-pixels SPXn. The electrodes RME may be extended in the second direction DR2 to be disposed across the emission area EMA and the subsidiary area SA of the sub-pixel SPXn, and they may be spaced apart from one another in the first direction DR1. The electrodes RME may also be disposed in a bank storage portion IRP, which will be described later.

The display device 10 may include a first electrode RME1, a second electrode RME2, and a third electrode RME3 disposed on each of the sub-pixels SPXn. For example, the first electrode RME1 may be disposed at the center of the emission area EMA, the second electrode RME2 may be spaced apart from the first electrode RME1 in the first direction DR1 and may be disposed on the left side of the center of the emission area EMA, and the third electrode RME3 may be spaced apart from the first electrode RME1 in the first direction DR1 and may be disposed on the right side of the center of the emission area EMA.

The first electrode RME1 may be disposed on the second bank pattern BP2 disposed at the center of the emission area EMA, the second electrode RME2 may be partially disposed on the first bank pattern BP1 disposed on the left side of the emission area EMA, and the third electrode RME3 may be partially disposed on the first bank pattern BP1 disposed on the right side of the emission area EMA. The electrodes RME may be disposed at least on the inclined side surfaces of the bank patterns BP1 and BP2. According to an embodiment of the disclosure, the width of the first electrode RME1 in the first direction DR1 may be greater than that of the second bank pattern BP2. The width of the second electrode RME2 and the third electrode RME3 in the first direction DR1 may be smaller than that of first bank pattern BP1. At least a portion of each of the electrodes RME may be disposed directly on the via layer VIA so that they may be disposed on the same plane.

According to an embodiment of the disclosure, the first electrode RME1 may be disposed in each of the sub-pixels SPXn, while each of the second electrode RME2 and the third electrode RME3 may be disposed across other adjacent sub-pixels SPXn in the first direction DR1. The second electrode RME2 may include a first stem portion RM_S11, and a (1-1) branch portion RM_E11 and a (1-2) branch portion RM_E12 branching off from the first stem portion RM_S11 in two ways. The (1-1) branch portion RM_E11 branching off from the first stem portion RM_S11 may be adjacent to and face the first electrode RME1, while the (1-2) branch portion RM_E12 may be disposed in another sub-pixel SPXn spaced apart from it in the first direction DR1. The (1-1) branch portion RM_E11 and the (1-2) branch portion RM_E12 of the second electrode RME2 may be branched in the emission area EMA, and may merge into the first stem portion RM_S11 again in the subsidiary area SA.

The third electrode RME3 may include a second stem portion RM_S21, and a (2-1) branch portion RM_E21 and a (2-2) branch portion RM_E22 branching off from the second stem portion RM_S21 in two ways. The (2-1) branch portion RM_E21 branching off from the second stem portion RM_S21 may be disposed in another sub-pixel SPXn spaced apart from it in the first direction DR1, while the (2-2) branch portion RM_E22 may be adjacent to and face the first electrode RME1. The (2-1) branch portion RM_E21 and the (2-2) branch portion RM_E22 of the third electrode RME3 may be branched in the emission area EMA, and may merge into the second stem portion RM_S21 again in the subsidiary area SA.

In the emission area EMA of the second sub-pixel SPX2, the first electrode RME1, the (1-1) branch portion RM_E11 of the second electrode RME2, and the (2-2) branch portion RM_E22 of the third electrode RME3 may be disposed. Although the second electrode RME2 and the third electrode RME3 will be separately named and described for convenience of illustration, practically the second electrode RME2 and the third electrode RME3 may be one electrode. For example, from the viewpoint of another sub-pixel SPXn spaced apart from it in the first direction DR1, the third electrode RME3 may be the second electrode RME2.

The first electrode RME1, the second electrode RME2, and the third electrode RME3 may be electrically connected to the third conductive layer through a first via hole CTD1, a second via hole CTD2, and a third via hole CTS. The first electrode RME1 may be in electrical contact with a first conductive pattern CDP1 and a first voltage line VL1 through the first via hole CTD1 and the second via hole CTD2 penetrating through the via layer VIA and the passivation layer PV thereunder. The first via hole CTD1 may electrically connect the first electrode RME1 with the first conductive pattern CDP1 so that the first supply voltage of the first transistor T1 may be applied to the first electrode RME1 through the first conductive pattern CDP1. The second via hole CTD2 may electrically connect the first electrode RME1 with the first voltage line VL1 so that a signal for aligning the light-emitting elements ED may be applied to the first electrode RME1 through the first voltage line VL1. As will be described later, the first electrode RME1 may be separated at the separation region ROP after the light-emitting elements ED have been aligned, and thus it may receive no signal from the first voltage line VL1 and may receive a signal applied from the first transistor T1 through the first via hole CTD1.

The second electrode RME2 and the third electrode RME3 may be in electrical contact with the second voltage line VL2 through the third via hole CTS penetrating through the via layer VIA and the passivation layer PVX thereunder. The first electrode RME1 may be electrically connected to the first transistor T1 through the first conductive pattern CDP1 to receive the first supply voltage. The second electrode RME2 and the third electrode RME3 may be electrically connected to the second voltage line VL2 to receive the second supply voltage.

The first electrodes RME1 disposed in different sub-pixels SPXn adjacent to each other in the second direction DR2 or the opposite direction may be spaced apart from each other at the separation region ROP in the subsidiary area SA. Such arrangement of the first electrodes RME1 may be made by forming single electrode lines extended in the second direction DR2 and disposing the light-emitting elements ED thereon, and then separating the electrode lines into parts in a subsequent process. The electrode lines may be used to generate an electric field in the sub-pixel SPXn to align the light-emitting elements ED during the process of fabricating the display device 10.

After aligning the light-emitting elements ED, the electrode lines may be separated at the separation region ROP1, such that the electrodes RME spaced apart from each other in the second direction DR2 may be formed. The process of separating the electrode lines may be carried out after the process of forming the second insulating layer PAS2, and the second insulating layer PAS2 may not be disposed at the separation region ROP. The second insulating layer PAS2 may be utilized as a mask pattern in a process of separating the electrode lines.

The electrodes RME may be electrically connected to the light-emitting elements ED. The electrodes RME may be electrically connected to the light-emitting elements ED through the connection electrodes CNE: CNE1, CNE2 and CNE3 to be described below, and may transmit electric signals applied from a conductive layer thereunder to the light-emitting elements ED.

Each of the electrodes REM may include a conductive material having a high reflectance. For example, the electrodes RME may include a metal such as silver (Ag), copper (Cu), and aluminum (Al) as the material having a high reflectance, and may include an alloy such as aluminum (Al), nickel (Ni), lanthanum (La), etc. The electrodes RME may reflect light that is emitted from the light-emitting elements ED and travels toward the side surfaces of the bank patterns BP1 and BP2 toward the upper side of each of the sub-pixels SPXn.

It is, however, to be understood that the disclosure is not limited thereto. The electrodes RME may include a transparent conductive material. For example, each of the electrodes RME may include a material such as ITO, IZO and ITZO. In some embodiments, each of the electrodes RME1 and RME2 may have a structure in which one or more layers of a transparent conductive material and one or more metal layers having high reflectivity are stacked each other, or may be made up of a single layer including them. For example, each of the electrodes RME may have a stacked structure such as ITO/Ag/ITO/, ITO/Ag/IZO, and ITO/Ag/ITZO/IZO.

The first insulating layer PAS1 may be disposed on the via layer VIA, the bank patterns BP1 and BP2, and the electrodes RME. The first insulating layer PAS1 may be disposed on the via layer VIA to cover the electrodes RME and the bank patterns BP1 and BP2. The first insulating layer PAS1 may not be disposed at the separation region ROP of the subsidiary area SA. The first insulating layer PAS1 may protect the electrodes RME and may insulate different electrodes RME from each other. The first insulating layer PAS1 may also prevent that the light-emitting elements ED disposed thereon are brought into contact with other elements and damaged. In an embodiment, the first insulating layer PAS1 may have steps so that a portion of the upper surface is recessed between the electrodes RME spaced apart from each other in the first direction DR1. The light-emitting elements ED may be disposed at the steps of the upper surface of the first insulating layer PAS1, and space may be formed between the light-emitting elements ED and the first insulating layer PAS1. The space may be filled with the second insulating layer PAS2, which will be described later.

The first insulating layer PAS1 may include multiple contacts CT1 and CT2 exposing a portion of the upper surface of each of the electrodes RME. The contacts CT1 and CT2 may penetrate through the first insulating layer PAS1. The first connection electrode CNE1 and the second connection electrode CNE2 described later may be in contact with the electrodes RME exposed through the contacts CT1 and CT2.

The bank layer BNL may be disposed on the first insulating layer PAS1. The bank layer BNL may be disposed in a ladder pattern including parts extended in the first direction DR1 and the second direction DR2 in a plan view, and may be disposed at the boundaries of the sub-pixels SPXn to distinguish the adjacent sub-pixels SPXn from each other. The bank layer BNL may be disposed to surround the emission area EMA and the subsidiary area SA. The areas defined and opened by the bank layer BNL may be the emission area EMA and the subsidiary area SA.

The bank layer BNL may have a predetermined (or selectable) height, and in some embodiments, the height of the upper surface of the bank layer BNL may be higher than the bank patterns BP1 and BP2, and its thickness may be equal to or greater than the bank patterns BP1 and BP2. It should be understood that the disclosure is not limited thereto. The height of the upper surface of the bank layer BNL may be equal to or less than that of the bank patterns BP1 and BP2, and its thickness may be smaller than that of the bank patterns BP1 and BP2. The bank layer BNL may prevent an ink from overflowing into adjacent sub-pixels SPXn in the second direction DR2 during an inkjet printing process of the processes of fabricating the display device 10. The bank layer BNL may separate the different sub-pixels SPXn from one another so that the ink in which different light-emitting elements ED are dispersed are not mixed. The bank layer BNL may include, but is not limited to, polyimide, like the bank patterns BP1 and BP2.

According to an embodiment of the disclosure, a portion of the bank layer BNL that is extended in the first direction DR1 may be higher than a portion of the bank layer BNL that is extended in the second direction DR2. The portion of the bank layer BNL that is extended in the first direction DR1 may prevent the ink from overflowing in the first direction DR1. The portion of the bank layer BNL that is extended in the second direction DR2 may separate the emission areas EMA, and may allow the ink to spread to adjacent sub-pixels SPXn in the first direction DR1. In other words, the ink may spread to the adjacent sub-pixels SPXn in the first direction DR1 to have a uniform thickness.

If the amount of ink applied to the sub-pixels SPXn is too much, the ink may overflow into the subsidiary area SA located in the first direction DR1 beyond the bank layer BNL. In case that this happens, inks may remain at the separation region ROP of the subsidiary area SA, and thus the first electrode RME1 disposed at the separation region ROP may be not separated in a subsequent process, resulting in a bright spot defect. A dark spot defect may also occur due to poor contact between the light-emitting elements ED and the electrodes CNE, or a film may be delaminated due to poor adhesion of the layers formed on the ink.

According to an embodiment of the disclosure, the bank layer BNL may include a bank guide portion BNP to prevent the ink from overflowing into the separation region ROP of the subsidiary area SA. The bank guide portion BNP may be disposed in the portion of the bank layer BNL that is extended in the first direction DR1. The bank guide portion BNP may be disposed in at least one sub-pixel SPXn of each pixel PXn. For example, the bank guide portion BNP may be disposed in the second sub-pixel SPX2 among the first sub-pixel SPX1, the second sub-pixel SPX2, and the third sub-pixel SPX3. In another embodiment, the bank guide portion BNP may be disposed in the first sub-pixel SPX1 or the third sub-pixel SPX3. The bank guide portion BNP may be disposed in at least one sub-pixel SPXn of one of the pixels PXn. For example, the bank guide portion BNP may be disposed in one sub-pixel SPXn of every two pixels PXn, or on sub-pixel SPXn of every three or more pixels PXn.

The bank guide portion BNP may be disposed between the emission area EMA and the bank storage portion IRP, and may be in contact with the emission area EMA of the respective sub-pixel SPXn and the bank storage portion IRP. The bank guide portion BNP may be disposed on a portion of the bank layer BNL that corresponds to an edge or a central portion of the emission area EMA. It is, however, to be understood that the disclosure is not limited thereto. The bank guide portion BNP may guide the ink applied in the emission areas EMA to flow from the emission areas EMA to the outside.

The bank guide portion BNP may have a cross-sectional shape different from that of the bank layer BNL so that ink may be guided. The cross-sectional shapes of the bank guide portion BNP and the bank layer BNL may be the one taken along the second direction DR2.

As shown in FIGS. 6 and 7, the bank guide portion BNP may have a height smaller than that of the bank layer BNL. For example, the height H1 of the bank guide portion BNP may be smaller than the height H2 of the bank layer BNL. The heights of the bank guide portion BNP and the bank layer BNL may be measured from the upper surface of the first insulating layer PAS1. The thickness of the bank guide portion BNP may be smaller than the thickness of the bank layer BNL. The ink confined in the bank layer BNL may flow out of the emission area EMA through the lower bank guide portion BNP.

The shape of the bank guide portion BNP may have other shapes so that ink may overflow.

As shown in FIG. 8, the bank guide portion BNP may have a shape in which its part is cut in the third direction DR3. In this embodiment, the width of the bank guide portion BNP may be smaller than the width of the bank layer BNL, and the height of the bank guide portion BNP may be equal to the height of the bank layer BNL. The ink may not overflow the bank layer BNL in case that it reaches a certain point due to surface tension on the surface of the bank layer BNL. However, it may flow over the bank layer BNL beyond the certain point. Such a point may be defined as a pinning point. According to this embodiment, the bank layer BNL may include the bank guide portion BNP that has the cross-sectional shape in which it is cut in the third direction DR3 at a point that is closer to the outside of the emission area EMA from the center L of the bank guide portion BNP (e.g., a point before the pinning point). In this embodiment, the ink may be not held on the surface of the bank guide portion BNP by surface tension but may flow along the cut surface. Accordingly, the shape of the bank guide portion BNP may guide the ink to flow out from the emission area EMA.

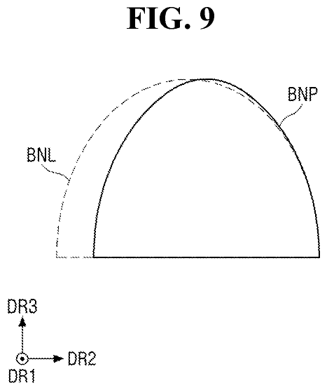

As shown in FIG. 9, the bank guide portion BNP may be formed to have a width smaller than that of the bank layer BNL. In this embodiment, the height of the bank guide portion BNP may be equal to the height of the bank layer BNL. In case that the width of the bank guide portion BNP is smaller than that of the bank layer BNL, the surface inclination of the bank guide portion BNP may increase, so that the pinning point becomes closer to the peak of the bank guide portion BNP. Accordingly, the ink may be guided so that it may flow over the bank guide portion BNP.

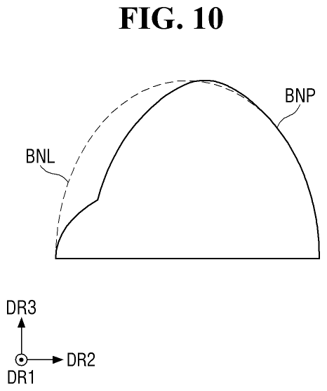

As shown in FIG. 10, the bank guide portion BNP may be formed in a shape having a step on a portion of the surface thereof. For example, the bank guide portion BNP may have a step on the surface that is opposite to the surface facing the emission area EMA. The bank guide portion BNP may have a larger height where it is closer to the emission area EMA and may have a smaller height where it is distant from the emission area EMA. In this embodiment, the bank guide portion BNP may guide the ink in the same manner as the embodiment in FIG. 9.

According to an embodiment of the disclosure, a dam portion DAM may be included which blocks the ink from flowing to the separation region ROP of the subsidiary area SA in case that the ink is guided to flow over the bank guide portion BNP. The dam portion DAM may be disposed between the emission areas EMA of the adjacent sub-pixels SPXn in the second direction DR2. The dam portion DAM may be disposed parallel to the portion of the bank layer BNL that is extended in the second direction DR2. The dam portion DAM and the bank layer BNL may be disposed on the same layer and may include the same material.

The dam portion DAM may separate the subsidiary area SA from the bank storage portion IRP. The bank storage portion IRP may be disposed on the side of the dam portion DAM in the second direction DR2, and the subsidiary area SA may be disposed on the opposite side in the second direction DR2. For example, the bank storage portion IRP may be disposed between the dam portion DAM and the emission areas EMA adjacent to them in the second direction DR2, and the subsidiary area SA may be disposed between the dam portion DAM and the other emission areas EMA adjacent to them on the opposite side in the second direction DR2. The dam portion DAM may be disposed between the subsidiary area SA of another sub-pixel SPXn on the opposite side in the second direction DR2 from the emission area EMA in which the bank guide portion BNP is disposed. The bank storage portion IRP may be disposed between the emission areas EMA and the subsidiary area SA. In the subsidiary area SA, there may be the separation region ROP where the first electrode RME1 is extended and disconnected. The dam portion DAM may be disposed between the bank guide portion BNP and the separation region ROP, and may not overlap the separation region ROP.

The dam portion DAM may confine the ink flowing out through the bank guide portion BNP in the bank storage portion IRP. To this end, as shown in FIG. 11, the height H3 of the dam portion DAM may be equal to the height H2 of the bank layer BNL. It should be understood, however, that the disclosure is not limited thereto. The height H3 of the dam portion DAM may be smaller than the height H2 of the bank layer BNL. The dam portion DAM may be formed in the same process as the bank layer BNL and may be made of the same material.

As described above, according to this embodiment, by forming the bank guide portion BNP and the dam portion DAM, the ink overflowing from the emission area EMA may be guided to flow into the bank storage portion IRP. Accordingly, it is possible to prevent bright spots, dark spots, film delamination, etc., which may occur if the ink overflows into the separation region ROP of the subsidiary area SA.

The light-emitting elements ED may be disposed on the first insulating layer PAS1. The light-emitting elements ED may include multiple layers disposed on the upper surface of the substrate SUB in the direction parallel to it. The light-emitting elements ED of the display device 10 may be arranged such that they are extended in parallel to the substrate SUB. The multiple semiconductor layers included in the light-emitting elements ED may be disposed sequentially in the direction parallel to the upper surface of the substrate SUB. It is, however, to be understood that the disclosure is not limited thereto. In some embodiments, in case that the light-emitting elements ED have a different structure, multiple layers may be disposed in a direction perpendicular to the substrate SUB.

The light-emitting elements ED may be disposed between the bank patterns BP1 and BP2 or on different electrodes RME. Some of the light-emitting elements ED may be disposed between the first bank pattern BP1 and the second bank pattern BP2, and some others may be disposed between another first bank pattern BP1 and another second bank pattern BP2. According to an embodiment of the disclosure, the light-emitting elements ED may include a first light-emitting element ED1 disposed between the first bank pattern BP1 disposed on the right side in the emission area EMA and the second bank pattern BP2, and a second light-emitting element ED2 disposed between the first bank pattern BP1 disposed on the left side in the emission area EMA and the second bank pattern BP2. The first light-emitting element ED1 may be disposed on the first electrode RME1 and the third electrode RME3, and the second light-emitting element ED2 may be disposed on the first electrode RME1 and the second electrode RME2. The first light-emitting element ED1 may be disposed on the right portion of the emission area EMA of the respective sub-pixel SPXn, and the second light-emitting element ED2 may be disposed on the left portion of the emission area EMA of the respective sub-pixel SPXn. It is to be noted that the light-emitting elements ED may not be categorized by their positions in the emission area EMA but may be categorized by connection relationships with the connection electrodes CNE, which will be described later. The both ends of the light-emitting elements ED may be in electrical contact with different connection electrodes CNE depending on the arrangement structure of the connection electrodes CNE, and light-emitting elements ED may be categorized into different light-emitting elements ED depending on the types of the connection electrodes CNE which they are in contact with.

The light-emitting elements ED may be in electrical contact with the connection electrodes CNE1, CNE2 and CNE3 so that they may be electrically connected to them. As a portion of the semiconductor layer of each of the light-emitting elements ED is exposed at the end surface of the direction in which they are extended, the exposed portion of the semiconductor layer may be in electrical contact with the connection electrodes CNE. The first end of the first light-emitting element ED1 may be in electrical contact with the first connection electrode CNE1 while the second end thereof may be in electrical contact with a portion of the third connection electrode CNE3 ((3_1) extended portion CN_E1). A first end of the second light-emitting element ED2 may be in electrical contact with the second connection electrode CNE2 while a second end thereof may be in electrical contact with another portion of the third connection electrode CNE3 ((3_2) extended portion CN_E2). Each of the light-emitting elements ED may be electrically connected to the electrodes RME and the conductive layers under the via layer VIA through the connection electrodes CNE, and an electric signal may be applied to it so that light of a particular wavelength range may be emitted.

The second insulating layer PAS2 may be disposed on the light-emitting elements ED and the first insulating layer PAS1. The second insulating layer PAS2 may be extended in the second direction DR2 between the bank patterns BP1 and BP2 and may include a pattern portion disposed on the light-emitting elements ED. The pattern portion may be disposed to partially surround the outer surface of the light-emitting elements ED, and may not cover both sides or both ends of the light-emitting elements ED. The pattern portion may form a linear or island pattern in each sub-pixel SPXn in a plan view. The pattern portion of the second insulating layer PAS2 may protect the light-emitting elements ED and fix the light-emitting elements ED during the process of fabricating the display device 10.

The second insulating layer PAS2 may be disposed to fill the space between light-emitting elements ED and the first insulating layer PAS1 thereunder. For example, the second insulating layer PAS2 may be first formed to completely cover the light-emitting elements ED, and then patterned to expose both ends of the light-emitting elements ED. A portion of the second insulating layer PAS2 may be used to fill the space between the light-emitting elements ED and the first insulating layer PAS1 thereunder.

A portion of the second insulating layer PAS2 may be disposed on the bank layer BNL, the dam portion DAM, the bank storage portion IRP, and the subsidiary area SA. The second insulating layer PAS2 may include contacts CT1 and CT2 disposed in the subsidiary area SA. The second insulating layer PAS2 may include a first contact CT1 overlapping the first electrode RME1 and a second contact CT2 overlapping the second electrode RME2. The contacts CT1 and CT2 may penetrate through the second insulating layer PAS2 in addition to the first insulating layer PAS1. Each of the first contact CT1 and the second contact CT2 may expose a portion of the upper surface of the first electrode RME1 or the second electrode RME2 thereunder.

The connection electrodes CNE1, CNE2 and CNE3 may include a first connection electrode CNE1 and a second connection electrode CNE2 that are first-type connection electrodes, and a third connection electrode CNE3 that is a second-type connection electrode.

The first connection electrode CNE1 may have a shape extended in the second direction DR2 and may be disposed on the first electrode RME1. A portion of the first connection electrode CNE1 disposed on the second bank pattern BP2 may overlap the first electrode RME1 and may be extended in the second direction DR2 from it to be disposed in the subsidiary area SA located on the upper side of the emission area EMA beyond the bank layer BNL. The first connection electrode CNE1 may be electrically connected to at least one of the first electrode RME1 and the first conductive pattern CDP1 through the first contact CT1 in the subsidiary area SA.

The second connection electrode CNE2 may have a shape extended in the second direction DR2 and may be disposed on the second electrode RME2. A portion of the second connection electrode CNE2 disposed on the first bank pattern BP2 may overlap the second electrode RME2 and may be extended in the second direction DR2 from it to be disposed in the subsidiary area SA located on the upper side of the emission area EMA beyond the bank layer BNL. The second connection electrode CNE2 may be in electrical contact with the second voltage line VL2 through a second contact CT2 in the subsidiary area SA. The first connection electrode CNE1 and the second connection electrode CNE2 may overlap the emission area EMA but not the bank storage portion IRP.

The first connection electrode CNE1 may be disposed adjacent to the second connection electrode CNE2 with the third connection electrode CNE3 therebetween. The first connection electrode CNE1 and the second connection electrode CNE2 may be disposed parallel to each other and may be extended across the emission area EMA and the subsidiary area SA.

The third connection electrode CNE3 may overlap the first electrode RME1 and the third electrode RME3. For example, the third connection electrode CNE3 may include third extended portions CN_E1 and CN_E2 extended in the second direction DR2, and a first connection portion CN_B1 connecting the third extended portions CN_E1 and CN_E2. The third extended portions may include a (3-1) extended portion CN_E1 and a (3-2) extended portion CN_2. The (3-1) extended portion CN_E1 may be disposed on the third electrode RME3 in the emission area EMA, and the (3-2) extended portion CN_E2 may be disposed on the first electrode RME1 in the emission area EMA. The first connection portion CN_B1 may be extended in the first direction DR1 on the bank layer BNL disposed on the lower side of the emission area EMA, and may electrically connect the (3-1) extended portion CN_E1 with the (3-2) extended portion CN_E2. The third connection electrode CNE3 may be disposed on the emission area EMA and the bank layer BNL, and may not be connected to the third electrode RME3. The first connection portion CN_B1 of the third connection electrode CNE3 may be disposed to overlap the bank guide portion BNP of the bank layer BNL. The third connection electrode CNE3 may be in a floating state that is not connected to other lines or electrodes. The third connection electrode CNE3 may transmit a signal applied through the light-emitting elements ED. The first light-emitting element ED1 and the second light-emitting element ED2 may be electrically connected to each other in series only through the third connection electrode CNE3.

The third insulating layer PAS3 may be disposed on the third connection electrode CNE3, the first insulating layer PAS1, and the second insulating layer PAS2. The third insulating layer PAS3 may cover the third connection electrode CNE3 to insulate it from the adjacent first connection electrode CNE1 and second connection electrode CNE2. The first connection electrode CNE1 and the second connection electrode CNE2 may be disposed on the third insulating layer PAS3.

Although not shown in the drawings, an additional insulating layer may be further disposed on the third insulating layer PAS3, the first connection electrode CNE1, and the second connection electrode CNE2. The additional insulating layer may protect the elements disposed on the substrate SUB from the external environment. Each of the above-described first insulating layer PAS1, second insulating layer PAS2, and third insulating layer PAS3 may include an inorganic insulating material or an organic insulating material.

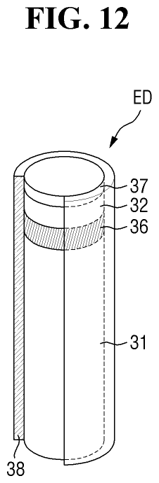

FIG. 12 is a perspective view showing a light-emitting element according to an embodiment of the disclosure.

Referring to FIG. 12, a light-emitting element ED may be a light-emitting diode. For example, the light-emitting element ED may have a size from nanometers to micrometers and may be an inorganic light-emitting diode made of an inorganic material. The light-emitting element ED may be aligned between two electrodes facing each other as polarities are created by forming an electric field in a particular direction between the two electrodes.

The light-emitting element ED according to an embodiment may have a shape extended in one direction. The light-emitting element ED may have a shape of a cylinder, a rod, a wire, a tube, etc. It is to be understood that the shape of the light-emitting element ED is not limited thereto. The light-emitting element ED may have a variety of shapes including a polygonal column shape such as a cube, a cuboid, and a hexagonal column, or a shape that is extended in a direction with partially inclined outer surfaces.

The light-emitting element ED may include semiconductor layers doped with impurities of a conductive type (e.g., p-type or n-type). The semiconductor layers may emit light of a certain wavelength band by receiving an electric signal applied from an external power source. The light-emitting element ED may include a first semiconductor layer 31, a second semiconductor layer 32, an emissive layer 36, an electrode layer 37, and an insulating film 38.

The first semiconductor layer 31 may be an n-type semiconductor. The first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be one or more of n-type doped AlGaInN, GaN, AlGaN, InGaN, AlN, and InN. The n-type dopant doped into the first semiconductor layer 31 may be Si, Ge, Sn, etc.

The second semiconductor layer 32 may be disposed above the first semiconductor layer 31 with the emissive layer 36 therebetween. The second semiconductor layer 32 may be a p-type semiconductor, and may include a semiconductor material having the following chemical formula: AlₓGa_{y}In_{1-x-y}N (0≤x≤1, 0≤y≤1, 0≤x+y≤1). For example, the second semiconductor layer 32 may be one or more of p-type doped AlGaInN, GaN, AlGaN, InGaN, AlN, and InN. The p-type dopant doped into the second semiconductor layer 32 may be Mg, Zn, Ca, Se, Ba, etc.

Although each of the first semiconductor layer 31 and the second semiconductor layer 32 is implemented as a signal layer in the drawings, the disclosure is not limited thereto. Depending on the material of the emissive layer 36, the first semiconductor layer 31 and the second semiconductor layer 32 may further include more layers, e.g., a clad layer or a tensile strain barrier reducing (TSBR) layer.

The emissive layer 36 may be disposed between the first semiconductor layer 31 and the second semiconductor layer 32. The emissive layer 36 may include a material having a single or multiple quantum well structure. In case that the emissive layer 36 includes a material having the multiple quantum well structure, the structure may include quantum layers and well layers alternately stacked each other. The emissive layer 36 may emit light as electron-hole pairs are combined therein in response to an electrical signal applied through the first semiconductor layer 31 and the second semiconductor layer 32. The emissive layer 36 may include a material such as AlGaN and AlGaInN. In particular, in case that the emissive layer 36 has a multi-quantum well structure in which quantum layers and well layers are alternately stacked each other, the quantum layers may include AlGaN or AlGaInN, and the well layers may include a material such as GaN and AlGaN.

The emissive layer 36 may have a structure in which a semiconductor material having a large band gap energy and a semiconductor material having a small band gap energy are alternately stacked each other, and may include Group III to Group V semiconductor materials depending on the wavelength range of the emitted light. The light emissive layer 36 may emit light of blue wavelength band. However, the light emitted from the emissive layer 36 is not limited to the light of the blue wavelength band. The emissive layer 36 may emit light of red or green wavelength band in some embodiments.

The electrode layer 37 may be an ohmic connection electrode. It is, however, to be understood that the disclosure is not limited thereto. The electrode layer 37 may be a Schottky connection electrode. The light-emitting element ED may include at least one electrode layer 37. The light-emitting element ED may include one or more electrode layers 37. It is, however, to be understood that the disclosure is not limited thereto. The electrode layer 37 may be omitted.

The electrode layer 37 may reduce the resistance between the light-emitting element ED and the electrodes or the connection electrodes in case that the light-emitting element ED is electrically connected to the electrodes or the connection electrodes in the display device 10. The electrode layer 37 may include a metal having conductivity. For example, the electrode layer 37 may include at least one of aluminum (Al), titanium (Ti), indium (In), gold (Au), silver (Ag), ITO, IZO and ITZO.

The insulating film 38 may be disposed to surround the outer surfaces of the of semiconductor layers and electrode layers described above. For example, the insulating film 38 may be disposed to surround at least the outer surface of the emissive layer 36, with both ends of the light-emitting element ED in the longitudinal direction exposed. A portion of the upper surface of the insulating film 38 may be rounded in cross-sectional view, which is adjacent to at least one of the ends of the light-emitting element ED.

The insulating film 38 may include materials having insulating properties such as silicon oxide (SiOx), silicon nitride (SiNx), silicon oxynitride (SiOxNy), aluminum nitride (AlNx), and aluminum oxide (AlOx). Although the insulating film 38 is formed as a single layer in the drawings, the disclosure is not limited thereto. In some embodiments, the insulating film 38 may be made up of a multilayer structure in which multiple layers are stacked each other.

The insulating film 38 may protect the above-described elements. The insulating film 30 may prevent an electrical short-circuit that may occur in the emissive layer 36 in case that it comes in direct contact with an electrode through which an electric signal is transmitted to the light-emitting element ED. The insulating film 38 may prevent a decrease in luminous efficiency.

The outer surface of the insulating film 38 may be subjected to surface treatment. The light-emitting elements ED may be dispersed in an ink, and the ink may be sprayed onto the electrode. A surface treatment may be applied to the insulating film 38 so that it becomes hydrophobic or hydrophilic in order to keep the light-emitting elements ED dispersed in the ink without being aggregated with one another.

Hereinafter, display devices according to other embodiments of the disclosure will be described with reference to other drawings.

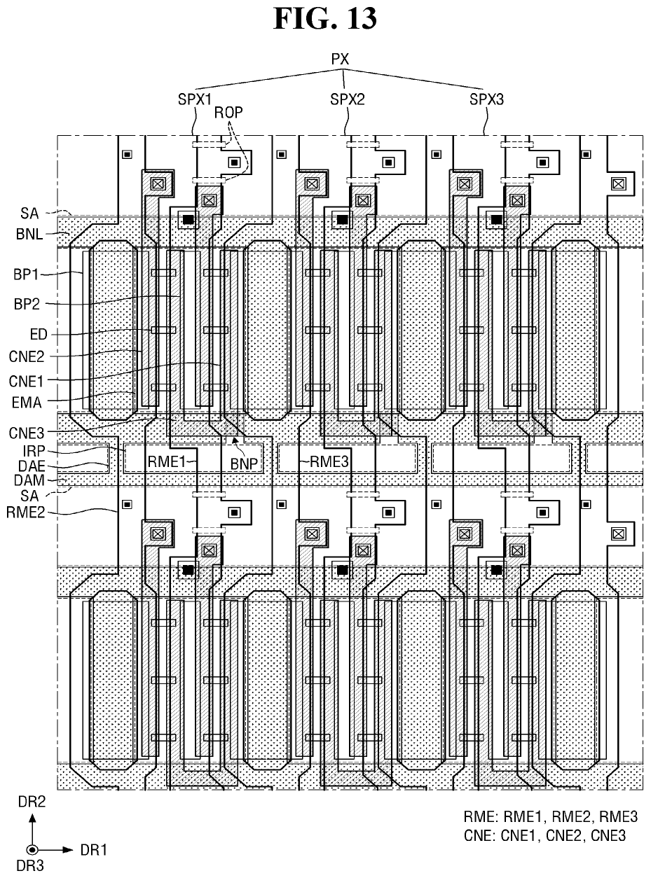

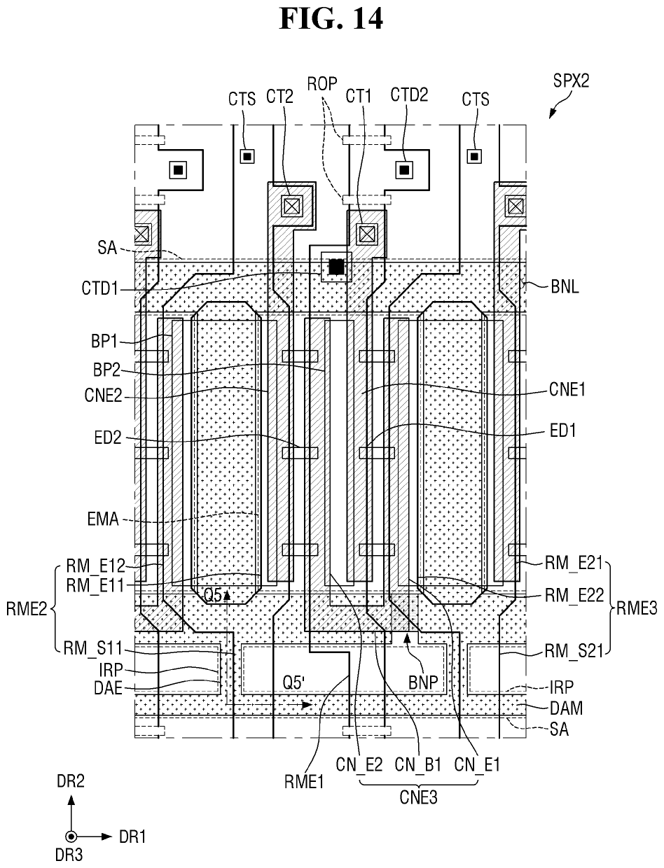

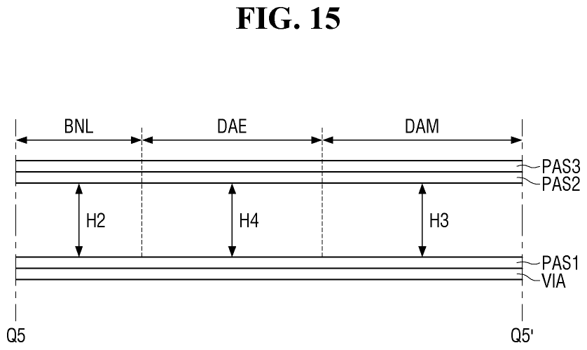

FIG. 13 is a plan view showing a pixel of a display device according to another embodiment of the disclosure. FIG. 14 is a plan view showing the first sub-pixel of FIG. 13. FIG. 15 is a schematic cross-sectional view taken along line Q5-Q5′ of FIG. 14.

The embodiment of FIGS. 13 to 15 is different from the above-described embodiment in that a dam portion DAM further includes a dam extension DAE connected to a bank layer BNL, and a bank guide portion BNP is disposed in each sub-pixel SPXn. In the following description, the description will focus on the difference and the redundant description will be omitted.

According to this embodiment, the light-emitting elements ED disposed in each of the sub-pixels SPXn may emit different lights. For example, light-emitting elements ED that emit light of the first color may be disposed in the first sub-pixel SPX1, light-emitting elements ED that emit light of the second color may be disposed in the second sub-pixel SPX2, and light-emitting elements ED that emit light of the third color may be disposed in the third sub-pixel SPX3. The bank layer BNL may prevent different inks applied to the respective sub-pixels SPXn from overflowing into adjacent sub-pixels SPXn. To this end, the portion of the bank layer BNL that is extended in the first direction DR1 may be similar to the portion of the bank layer BNL that is extended in the second direction DR2. The bank layer BNL may prevent the ink from overflowing into the adjacent sub-pixels SPXn in the first direction DR1 and the second direction DR2.

The bank layer BNL may include a bank guide portion BNP to prevent the ink from overflowing into the separation region ROP of the subsidiary area SA. The bank guide portion BNP may be disposed in the portion of the bank layer BNL of each sub-pixel SPXn that is extended in the first direction DR1. For example, the bank guide portion BNP may be disposed on a portion of the bank layer BNL in the first sub-pixel SPX1 that is adjacent to the dam portion DAM and is extended in the first direction DR1. Likewise, the bank guide portion BNP may be disposed on a portion of the bank layer BNL in each of the second sub-pixel SPX2 and the third sub-pixel SPX3 that is adjacent to the dam portion DAM and is extended in the first direction DR1.

The dam portion DAM may include a dam extension DAE that prevents different inks flowing through the bank guide portion BNP of each sub-pixel SPXn from being mixed. The dam extension DAE may be extended in the second direction DR2 from the dam portion DAM and may be extended toward the bank guide portion BNP of each sub-pixel SPXn. The dam extension DAE may be extended in the direction crossing the dam portion DAM and may be disposed parallel to the portion of the bank layer BNL in the second direction DR2. The dam extension DAE may be disposed between the dam portion DAM and the bank layer BNL

The dam portion DAM and the dam extension DAE may separate the bank storage portion IRP from the subsidiary area SA and the bank layer BNL. The bank storage portion IRP may be disposed in an area surrounded by the dam portion DAM and the dam extension DAE, and the subsidiary area SA may be disposed in an area surrounded by the dam portion DAM and the bank layer BNL. Each of the sub-pixels SPXn may include a bank storage portion IRP, and the sub-pixels SPXn may share the subsidiary area SA. The bank storage portion IRP may be disposed parallel with the emission area EMA of the respective sub-pixel SPXn in the second direction DR2. For example, each of the first sub-pixel SPX1, the second sub-pixel SPX2, and the third sub-pixel SPX3 may include a bank storage portion IRP adjacent to the emission area EMA, and may share one subsidiary area SA adjacent to the bank storage portion IRP with the dam portion DAM therebetween. The dam extension DAE may be extended to the bank layer BNL where the bank guide portion BNP is disposed as a single piece. The dam extension DAE may be formed via the same process as the bank layer BNL, like the dam portion DAM. The bank layer BNL, the bank guide portion BNP, the dam extension DAE, and the dam portion DAM may be continuously extended and arranged. The height H4 of the dam extension DAE may be equal to the height H3 of the dam portion DAM and the height H2 of the bank layer BNL. It should be understood, however, that the disclosure is not limited thereto. The height H4 of the dam extension DAE and the height H3 of the dam portion DAM may be smaller than the height H2 of the bank layer BNL, or the height H4 of the dam extension DAE may be smaller than the height H3 of the dam portion DAM and the height H2 of the bank layer BNL.

As described above, in the display device 10 according to the embodiments, in case that different inks are applied to the sub-pixels SPXn, the dam portion DAM and the dam extension DAE may be disposed so that each of the sub-pixels SPXn has the bank guide portion BNP and the bank storage portion IRP. Accordingly, it is possible to prevent that the different inks are introduced from different sub-pixel SPXn into the bank storage portion IRP and are mixed.

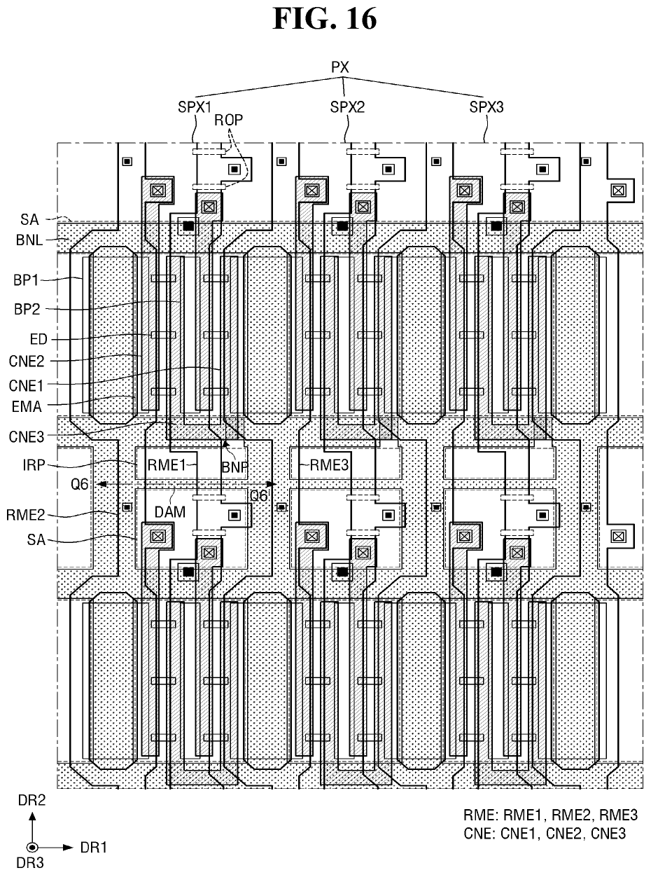

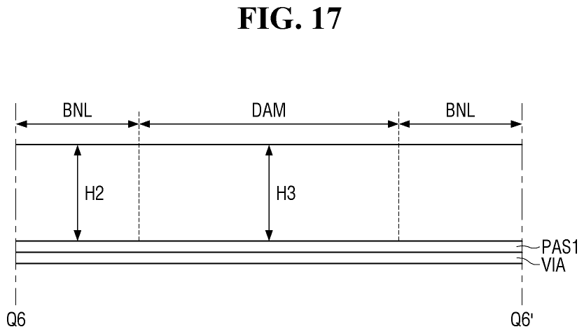

FIG. 16 is a plan view showing a pixel of a display device according to yet another embodiment of the disclosure. FIG. 17 is a schematic cross-sectional view taken along line Q6-Q6′ of FIG. 16.

The embodiment of FIGS. 16 and 17 is different from the embodiment of FIG. 13 in that a bank layer BNL is formed in a lattice pattern. In the following description, the description will focus on the difference and the redundant description will be omitted.

The bank layer BNL may be disposed in a lattice pattern including parts extended in the first direction DR1 and the second direction DR2 in a plan view, and may be disposed at the boundaries of the sub-pixels SPXn to distinguish the adjacent sub-pixels SPXn from each other. The bank layer BNL may be disposed to surround the emission area EMA and the subsidiary area SA. The areas defined and opened by the bank layer BNL may be the emission area EMA and the subsidiary area SA.

According to an embodiment of the disclosure, a dam portion DAM may be included which blocks the ink from flowing to the separation region ROP of the subsidiary area SA. The dam portion DAM may be disposed between the adjacent emission areas EMA of the sub-pixels SPXn in the second direction DR2. The dam portion DAM may be disposed parallel to the portion of the bank layer BNL that is extended in the second direction DR2. Unlike the embodiment of FIGS. 13 to 15, the dam portion DAM may be disposed to cross in the first direction DR1 between the bank layers BNL extended in the second direction DR2.

The dam portion DAM may separate the subsidiary area SA from the bank storage portion IRP. The dam portion DAM may be surrounded by the bank layer BNL and may separate the bank storage portion IRP from the subsidiary area SA. The bank storage portion IRP may be disposed on a side of the dam portion DAM in the second direction DR2, and the subsidiary area SA may be disposed on the opposite side in the second direction DR2. For example, the bank storage portion IRP may be disposed between the dam portion DAM and the emission areas EMA adjacent to them in the second direction DR2, and the subsidiary area SA may be disposed between the dam portion DAM and other emission areas EMA adjacent to them on the opposite side in the second direction DR2. The dam portion DAM may be disposed between the subsidiary area SA of another sub-pixel SPXn on the opposite side in the second direction DR2 from the emission area EMA in which the bank guide portion BNP is disposed.

The dam portion DAM may be extended from the bank layer BNL and may be integrated with the bank layer BNL. The dam portion DAM may be formed together with the bank layer BNL via the same process. The bank layer BNL, the bank guide portion BNP, and the dam portion DAM may be continuously connected, disposed on the same layer, and may include the same material. The height H3 of the dam portion DAM may be equal to the height H2 of the bank layer BNL. It should be understood, however, that the disclosure is not limited thereto. The height H3 of the dam portion DAM may be smaller than or greater than the height H2 of the bank layer BNL.

As described above, in the display device 10 according to the embodiments, in case that different inks are applied to the sub-pixels SPXn, the dam portion DAM may be disposed so that each of the sub-pixels SPXn has the bank guide portion BNP and the bank storage portion IRP. Accordingly, it is possible to prevent that the different inks are introduced from different sub-pixel SPXn into the bank storage portion IRP and are mixed.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a plurality of sub-pixels comprising emission areas, and a subsidiary area;
a via layer disposed on a substrate;
a bank layer disposed on the via layer and separating the emission areas of the plurality of sub-pixels from one another;
a dam portion disposed between the bank layer and adjacent bank layer and separating a bank storage portion from the subsidiary area;
a first electrode and a second electrode disposed on the via layer in at least one of the emission areas and spaced apart from each other; and
a light-emitting element disposed on the first electrode and the second electrode, wherein
the bank layer comprises a bank guide portion disposed between the at least one of the emission areas and the bank storage portion, and
a shape of the bank guide portion is different from a shape of a rest of the bank layer in a cross-sectional view.

2. The display device of claim 1, wherein
the emission areas are spaced apart from one another in a first direction,
the bank storage portion is spaced apart from the emission areas in a second direction intersecting the first direction,
the subsidiary area is spaced apart from the bank storage portion in the second direction, and
the bank storage portion is disposed between the emission areas and the subsidiary area.

3. The display device of claim 2, wherein
the shape of the bank guide portion in the cross-sectional view is defined by cutting the bank guide portion in the second direction, and
the shape of the rest of the bank layer in the cross-sectional view is defined by cutting the bank layer in the second direction.

4. The display device of claim 2, wherein a width of the bank guide portion is smaller than a width of the rest of the bank layer in the second direction.

5. The display device of claim 4, wherein a height of the bank guide portion is equal to a height of the rest of the bank layer in a thickness direction of the bank layer.

6. The display device of claim 2, wherein a height of the bank guide portion is smaller than a height of the rest of the bank layer in a thickness direction of the bank layer.

7. The display device of claim 6, wherein a width of the bank guide portion is equal to a width of the rest of the bank layer in the second direction.

8. The display device of claim 2, wherein
the dam portion extends in the first direction, and
a height of the dam portion is equal to a height of the bank layer in a thickness direction of the bank layer.

9. The display device of claim 8, wherein a width of the dam portion is smaller than a width of the bank layer in the second direction.

10. The display device of claim 2, wherein
the dam portion comprises a plurality of dam extensions extending in the second direction and disposed adjacent to the bank guide portion, and
the plurality of dam extensions and the bank layer are integral with each other.

11. The display device of claim 10, wherein the bank storage portion is defined by the plurality of dam extensions, the bank layer comprising the bank guide portion, and the dam portion.

12. The display device of claim 11, wherein the bank storage portion is in one to one correspondence with each of the emission areas of the plurality of sub-pixels in the second direction.

13. The display device of claim 11, wherein the bank guide portion is disposed between the at least one of the emission areas and the bank storage portion and is in contact with the at least one of the emission areas and the bank storage portion.

14. The display device of claim 1, wherein the dam portion and the bank layer are disposed on a same layer and comprise a same material.

15. A display device comprising:
a plurality of sub-pixels comprising emission areas, and a subsidiary area;
a via layer disposed on a substrate;
a bank layer disposed on the via layer and separating the emission areas of the plurality of sub-pixels from one another;
a dam portion surrounded by the bank layer on the via layer and separating a bank storage portion from a subsidiary area;
a first electrode and a second electrode disposed on the via layer in at least one of the emission areas and spaced apart from each other; and
a light-emitting element disposed on the first electrode and the second electrode, wherein
the bank storage portion and the subsidiary area are surrounded by the bank layer and are separated and divided by the dam portion,
the bank layer comprises a bank guide portion disposed between the at least one of the emission areas and the bank storage portion, and
a shape of the bank guide portion is different from a shape of a rest of the bank layer in a cross-sectional view.

16. The display device of claim 15, wherein
the emission areas are spaced apart from one another in a first direction,
the bank storage portion is spaced apart from the emission areas in a second direction intersecting the first direction,
the subsidiary area is spaced apart from the bank storage portion in the second direction, and
the bank storage portion is disposed between the emission areas and the subsidiary area.

17. The display device of claim 16, wherein
the first electrode extends to the subsidiary area, and
the subsidiary area comprises a separation region disconnecting the first electrode.

18. The display device of claim 17, wherein the dam portion is disposed between the bank guide portion and the separation region, and does not overlap the separating region in a plan view.

19. The display device of claim 15, wherein the bank layer and the dam portion are integral with each other, are disposed on a same layer, and comprise a same material.

20. The display device of claim 15, further comprising:
a first connection electrode in electrical contact with a first end of the light-emitting element; and
a second connection electrode in electrical contact with a second end of the light-emitting element,
wherein the first connection electrode and the second connection electrode overlap the at least one of the emission areas in a plan view, and do not overlap the bank storage portion in the plan view.
